(19) United States
(12) Patent Application Publication
(10) Pub. No.: US 2025/0123323 A1
(43) Pub. Date: Apr. 17, 2025

(54) SEMICONDUCTOR TEST DEVICE AND METHOD OF MANUFACTURING THE SAME

(71) Applicant: SAMSUNG ELECTRONICS CO., LTD., Suwon-si (KR)

(72) Inventors: Haewook PARK, Suwon-si (KR); Sungyeol KIM, Suwon-si (KR); Junhyung KIM, Suwon-si (KR); Seongkwan LEE, Suwon-si (KR); Jaemoo CHOI, Suwon-si (KR)

(21) Appl. No.: 18/628,896

(22) Filed: Apr. 8, 2024

(30) Foreign Application Priority Data
Oct. 17, 2023 (KR) 10-2023-0138326

(51) Int. Cl. G01R 31/28; H01L 21/66

(52) U.S. Cl. CPC G01R 31/2877; G01R 31/2863; H01L 22/00

(57) ABSTRACT

A semiconductor test device includes a test chamber having at least one device under test disposed therein. A test module tests the at least one device under test. A signal connection device electrically connects the at least one device under test and the test module to each other. The signal connection device includes an electrically conductive thermal insulator (ECTI). The ECTI has electrical conductivity greater than or equal to about 1700 S/cm and thermal conductivity less than or equal to about 2.2 W/mK.

### CROSS-REFERENCE TO RELATED APPLICATION

This application claims priority under 35 U.S.C. § 119 to Korean Patent Application No. 10-2023-0138326, filed on Oct. 17, 2023 in the Korean Intellectual Property Office, the disclosure of which is incorporated by reference in its entirety herein.

### 1. TECHNICAL FIELD

The present inventive concept relates to a semiconductor test device and a method of manufacturing the same.

### 2. DISCUSSION OF RELATED ART

Various tests are typically conducted during semiconductor post-processing to verify the product performance. In particular, tests are conducted within a predetermined temperature range to determine whether the semiconductor product operates normally. During this process, various signals are applied to the semiconductor product being tested to determine whether the semiconductor operates at the maximum and minimum guaranteed temperatures. This temperature test is generally performed during a specific frame cycle. Distortion in signals transmitted and received by the device under test and a test module under the temperature conditions inside a chamber set for the test process should be prevented to provide accurate test results. With current technology, it takes a first period of time to change the temperature of the chamber. However, it takes an additional second period of time subsequent to the first period of time for the actual semiconductor product to reach the temperature for testing due to an unnecessary heat exchange between the test module and the inside of the chamber. As a result, the test process time may be significantly lengthened, energy may be unnecessarily consumed, and the test defect of the semiconductor product transmitting and receiving high-speed signals may negatively affect yield.

### SUMMARY

An aspect of embodiments of the present inventive concept is to provide a semiconductor test device and a method of manufacturing the same, capable of reducing test process time without signal distortion in a wide temperature range by minimizing heat exchange between a test chamber and a device under test.

According to an embodiment of the present inventive concept, a semiconductor test device includes a test chamber having at least one device under test disposed therein. A test module tests the at least one device under test. A signal connection device electrically connects the at least one device under test and the test module to each other. The signal connection device includes an electrically conductive thermal insulator (ECTI). The ECTI has electrical conductivity greater than or equal to about 1700 S/cm and thermal conductivity less than or equal to about 2.2 W/mK.

According to an embodiment of the present inventive concept, a semiconductor test device includes a probe card contacting pads of a device under test. A pogo block receives output signals from the probe card. An interface board receives output signals from the pogo block, converts the received signals, and outputs the converted signals through a signal connector. A test device is connected to the interface board through the signal connector. The test device tests the device under test through signals received through the signal connector. At least one of the probe card, pogo block, interface board, and signal connector includes pins formed of an electrically conductive thermal insulator (ECTI). The ECTI has electrical conductivity greater than or equal to about 1700 S/cm and thermal conductivity less than or equal to about 2.2 W/mK.

According to an embodiment of the present disclosure, a semiconductor test device includes a rubber pad having a plurality of micro balls. A test board receives a device under test and tests the device under test. A test socket is pressed against the test board to electrically connect the device under test and the test board through the rubber pad. The rubber pad is formed of an electrically conductive thermal insulator (ECTI). The ECTI has electrical conductivity greater than or equal to about 1700 S/cm and thermal conductivity less than or equal to about 2.2 W/mK.

According to an embodiment of the present disclosure, a method of manufacturing a semiconductor test device includes manufacturing a test board. The test board is electrically connected to a test chamber having a device under test using an electrically conductive thermal insulator (ECTI). The ECTI has electrical conductivity greater than or equal to about 1700 S/cm and thermal conductivity less than or equal to about 2.2 W/mK.

### BRIEF DESCRIPTION OF DRAWINGS

The above and other aspects, features, and advantages of embodiments of the present inventive concept will be more clearly understood from the following detailed description, taken in conjunction with the accompanying drawings, in which:

FIG. 1 is a diagram illustrating a semiconductor test device according to an example embodiment of the present inventive concept;

FIG. 2 is a diagram for analyzing heat flow when applying an electrically conductive thermal insulator (ECTI) in a semiconductor test device according to an example embodiment of the present inventive concept;

FIG. 3 is a diagram illustrating a semiconductor test device according to an example embodiment of the present inventive concept;

FIG. 4 is a diagram illustrating a pin provided in the semiconductor test device 20 according to an example embodiment of the present inventive concept;

FIG. 5 is a diagram illustrating a minimum force required to contact an uneven surface depending on the degree of bending of a pin in the semiconductor test device according to an example embodiment of the present inventive concept;

FIG. 6 is a diagram illustrating a semiconductor test device according to an example embodiment of the present inventive concept;

FIG. 7 is a diagram illustrating a semiconductor test device according to an example embodiment of the present inventive concept;

FIGS. 8A and 8B are diagrams illustrating a state before a test socket illustrated in FIG. 7 is closed and a state in which the test socket is closed according to example embodiments of the present inventive concept;

FIG. 9 is a diagram illustrating a test board 50 according to an example embodiment of the present inventive concept;

FIG. 10 is a diagram illustrating a test system 1000 according to an example embodiment of the present inventive concept; and

FIG. 11 is a flowchart illustrating a method of manufacturing a semiconductor test device according to an example embodiment of the present inventive concept.

### DETAILED DESCRIPTION OF EMBODIMENTS

Hereinafter, example embodiments of the present inventive concept will be described with reference to the accompanying drawings.

A semiconductor test device and a method for manufacturing the same according to an example embodiment may be implemented using an electrically conductive thermal insulator (ECTI). The semiconductor test device and an operating method thereof according to an embodiment of the present inventive concept may increase high-speed signal test performance of semiconductor products (e.g., signal integrity may be increased, the number of tests per unit area may increase, etc.) by disposing a test module closely to a device under test (DUT). The semiconductor test device and an operating method thereof according to an embodiment of the present inventive concept may reduce a high and low temperature (Hot↔Cold) variable time of a chamber during burn-in testing in an extreme temperature environment of a product and increase cooling/heating energy efficiency (e.g., save a facility operation budget). The semiconductor test device and a method of manufacturing the same according to an embodiment of the present inventive concept may prevent mechanical contact errors (e.g., increase test integrity) in a semiconductor test device by applying a bending structure to short pins, such as sockets, probe cards, and pogos.

An embodiment of the present inventive concept may apply an ECTI when implementing the semiconductor test device. To increase the productivity of the semiconductor test device, a chamber-type one-test device is provided to evaluate semiconductor products with high integration in extreme temperature environments. To maximize the productivity of the test process, the chamber-type one-test device places the DUT to be closer to a test module inside a chamber and performing a stack-up, thereby increasing the degree of integration of test products per unit facility area. Accordingly, as the DUT and test modules are stacked, the number of products that may be tested simultaneously per unit facility area increases. A decrease in the distance between the DUT and the test module may reduce losses in terms of high-speed signals, thereby increasing a bandwidth of testable signals. As a result, a positive effect is achieved in evaluating products that process semiconductor products requiring increasingly higher speeds.

However, if a chamber-type one-test device is implemented using a signal connection device (e.g., Cu, Ag, etc. having high electrical and thermal conductivity) of a general semiconductor test device, unnecessary heat transfer between a chamber and the test module may increase due to the reduced distance, resulting in a greater temperature transition time between high and low temperatures and reduction of electrical characteristics of test integrated circuits (ICs). This makes it difficult to implement a chamber-type one-test device that may unify burn-in testing, high-speed signal testing and low-speed signal testing such that each of these tests are performed using the same test device in the same test chamber.

A semiconductor test device and a method of manufacturing the same according to an embodiment may be implemented by applying the ECTI (having high electrical conductivity and low thermal conductivity) to a signal connection structure of the semiconductor test device. A semiconductor test device and a method of manufacturing the same according to an example embodiment may secure excellent high-speed signal evaluation characteristics by reducing unnecessary heat exchange between the DUT and the test module inside the chamber due to the insulating properties of the ECTI. In an embodiment, the semiconductor test device performs burn-in testing, high-speed signal testing and low-speed signal testing.

In addition, since the semiconductor test device and method of manufacturing the same according to an embodiment of the present inventive concept shortens a temperature transition time between high and low temperatures when evaluating products in extreme temperature environments, the productivity of a test process may be increased and a reduction of the facility operation budget may be expected due to an increase in the energy efficiency of cooling/heating of the chamber.

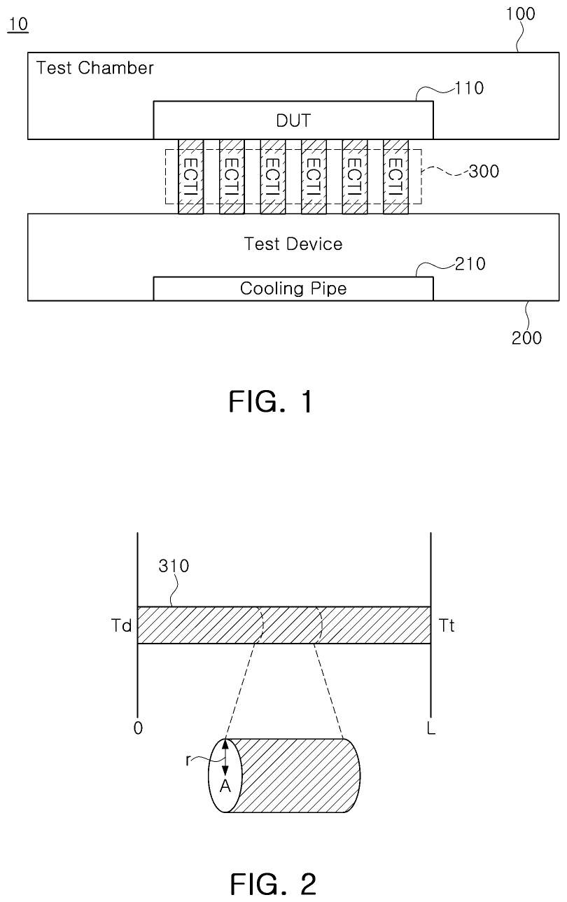

FIG. 1 is a diagram illustrating a semiconductor test device according to an example embodiment. Referring to FIG. 1, a semiconductor test device 10 may include a test chamber 100, a test module (e.g., a test device) 200, and a signal connection device 300. In an example embodiment, the semiconductor test device 10 may be implemented as a chamber-type one-test platform.

The test chamber 100 may be implemented to provide a sealed internal space for testing a device under test (DUT) 110. The test chamber 100 may further include a temperature sensor and an air hole. The test chamber 100 may be implemented to provide a heated or cooled environment inside the test chamber 100 to determine whether a semiconductor product operates and exhibits normal performance under predetermined temperature conditions. For example, in an embodiment the test chamber 100 may heat or cool the temperature inside the chamber using a convection phenomenon of air provided from the air hole included therein. In addition, the temperature sensor included inside the test chamber 100 may provide temperature information inside the chamber to a control device.

The test module 200 may be implemented to test the device under test 110 (e.g., DUT). In an embodiment, the test module 200 may include a cooling pipe 210 through which a cooling material (e.g., a refrigerant) flows to control a test temperature. In an example embodiment, the test module 200 may further include a temperature sensor detecting a temperature of the test module 200.

The signal connection device 300 may be implemented to electrically connect the device under test 110 and the test module 200. In an example embodiment, the signal connection device 300 may be implemented with the ECTI having high electrical conductivity and low thermal conductivity. In an example embodiment, the ECTI may be implemented to have an electrical conductivity greater than or equal to about 1700 S/cm (e.g., 5.9×10⁻⁶ ohm*m) and a thermal conductivity less than or equal to about 2.2 W/mK. For example, in an embodiment the ECTI may be formed of Al₂O₃-graphene nanocomposite material, Bi—Si nanocomposite material, carbon-ceramic electrospun nonwoven material, carbon nanotube sponge, multi-nanolayer graphene/ceramic metamaterial, and poly(3,4-ethylenedioxythiophene) polystyrene sulfonate (PEDOT:PSS).

In an example embodiment, the signal connection device 300 may include a cable, socket, probe card, printed-circuit board (PCB), low temperature co-fired ceramic (LTCC), or the like. In an example embodiment, the signal connection device 300 may include an electrical signal connection portion using the ECTI to transmit an electrical signal to the test module 200. In an example embodiment, the signal connection device 300 may use a material that does not have electrical conductivity in a portion other than the electrical signal connection portion.

In an embodiment, the semiconductor test device 10 may further include an air supply device spraying heated air or cooling air to control the temperature of the test chamber 100. In an example embodiment, the air supply device may be located outside the test chamber 100.

In a general semiconductor test device, a signal connection length between the device under test and the test module is relatively long, which may limit a test bandwidth of high-speed signals and increase test defects. In addition, in the general semiconductor test device, the productivity of the test process and facility operation energy efficiency may decrease due to a temperature change and stabilization time of the test chamber due to unnecessary heat conduction.

In contrast, the semiconductor test device 10 according to an embodiment of the present inventive concept may prevent heat exchange although the test module 200 is located close to the device under test DUT 110, thereby increasing the high-speed signal test performance of semiconductor products. In addition, since the semiconductor test device 10 of an embodiment of the present inventive concept includes the signal connection device 300 formed of the ECTI, the high-low temperature variable time of the test chamber 100 may be shortened and cooling/heating energy efficiency may be increased during burn-in testing in an extreme temperature environment of the product.

FIG. 2 is a diagram for analyzing heat flow when applying the ECTI in the semiconductor test device 10 according to an example embodiment. Referring to FIG. 2, the signal connection device 300 illustrated in FIG. 1 is illustrated as having a pin structure 310. When a length of a pin is L, a radius of the pin is r, thermal conductivity of the pin is k, a DUT temperature is Td, a test IC temperature is Tt, the number of pins is n, a cross-sectional area is A, and required cooling heat is Q, required cooling heat satisfies Equation 1 below.

$$Q = nkA / L ( {T}_{d} - {T}_{t} ) \qquad [ Equation 1 ]$$

In an embodiment, the semiconductor test device of the present inventive concept may be implemented with a pin connection structure, such as a socket, probe card, or pogo. In an embodiment, the semiconductor test device of an embodiment of the present inventive concept may increase a pad non-contact phenomenon caused by the lack of elasticity of the short pin by applying various bending structures, such as a bow shape, to the signal connection device.

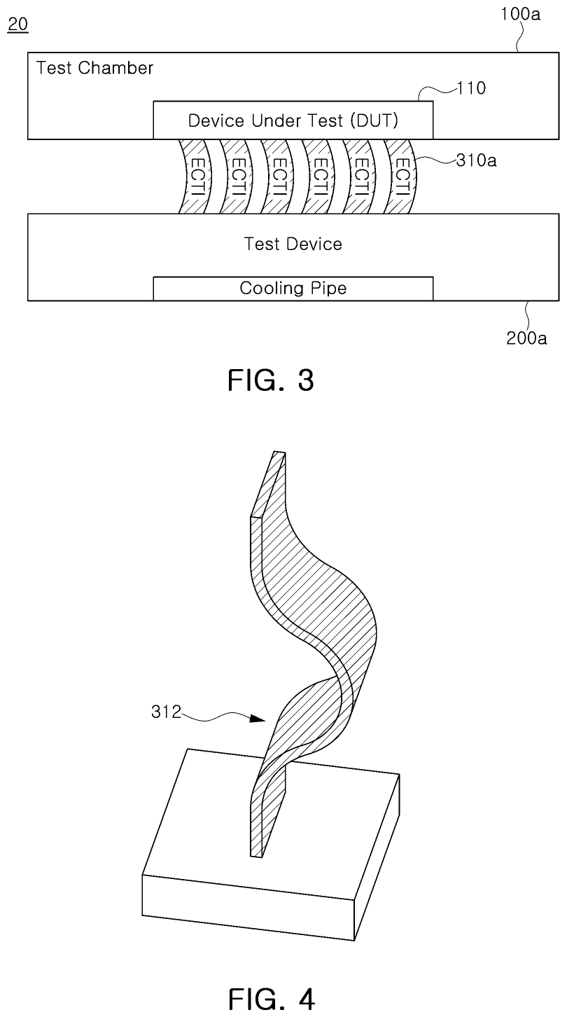

FIG. 3 is a diagram illustrating a semiconductor test device 20 according to an embodiment. Referring to FIG. 3, the semiconductor test device 20 may include a test chamber 100a, a test module (e.g., a test device) 200a, and a signal connection device 310a. Each of the test chamber 100a and the test module 200a may be implemented identically or similarly to the test chamber 100 and the test module 200 illustrated in FIG. 1.

The signal connection device 310a may include an ECTI implemented in a bending structure to increase contact integrity. In general, the bending structure may have a neutral axis that is not deformed when a force load is applied. In an embodiment, the neutral axis may be constant along a length of the structure or may change in position. Bending stress is proportional to a distance between a section area of the structure and the neutral axis and may vary depending on the size and shape of the structure and the size and location of a load. The effect of a bending load appears as the product of force of the bending load and the distance from a point at which the load acts. Flexural rigidity may be determined depending on the elastic modulus of a material and a shape of the structure.

As illustrated in FIG. 3, the minimum force required for contacting an uneven surface may be reduced through the signal connection device 300a having the bending structure. As a result, a pad non-contact phenomenon may be prevented even when a relatively small force is applied.

FIG. 4 is a diagram illustrating a pin 312 provided in the semiconductor test device 20 according to an example embodiment. Referring to FIG. 4, the pin 312 may be formed of an ECTI and may be implemented as a buckled column structure. In general, the buckled column structure may increase resistance to physical damage by providing additional rigidity or maintain the same performance while reducing material usage.

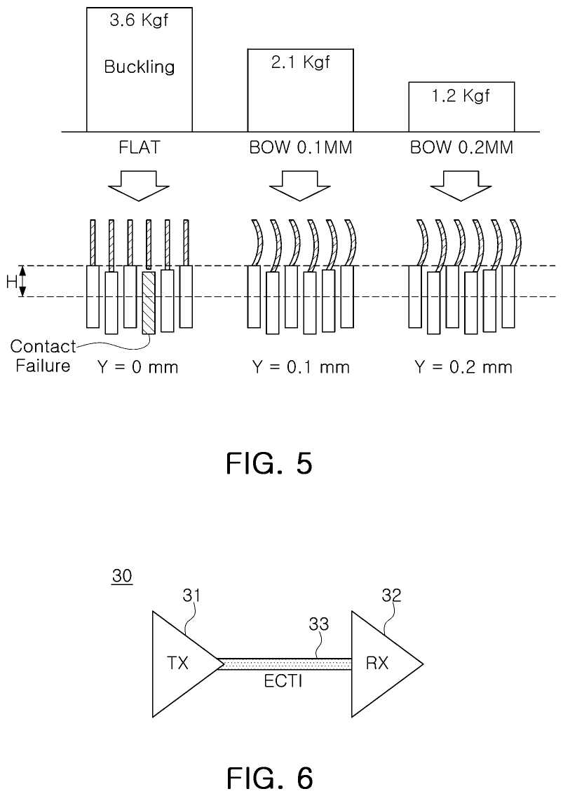

FIG. 5 is a diagram illustrating the minimum force required to contact an uneven surface depending on the degree of bending of a pin in the semiconductor test device 20 according to an example embodiment. Assuming that a length of the pin is 5 mm, a diameter of the pin is 0.1 mm, and a pad height difference H is 0.01 mm, a non-bending pin requires 3.6 kgf, a pin having a bending structure with a bending degree Y of 0.1 mm requires 2.1 kgf, and a pin having a structure with a bending degree Y of 0.2 mm requires 1.2 kgf. Buckling may occur if the structure is not curved, and contact failure may occur depending on the pad height difference H1. The pin having the bending structure according to an embodiment of the present inventive concept may prevent pad non-contact even when a relatively small amount of force is applied.

An embodiment of the present inventive concept is applicable to a test device having the ECTI between a transmitter and a receiver.

FIG. 6 is a diagram illustrating a semiconductor test device 30 according to an example embodiment. Referring to FIG. 6, the semiconductor test device 30 may include a transmitter 31, a receiver 32, and a signal connection device 33. The transmitter 31 may be implemented to output a transmission signal through the signal connection device 33. The receiver 32 may be implemented to receive the transmission signal through the signal connection device 33. In an embodiment, the signal connection device 33 may be implemented with the ECTI.

According to an embodiment of the present inventive concept, the ECTI may be applied to a test rubber socket.

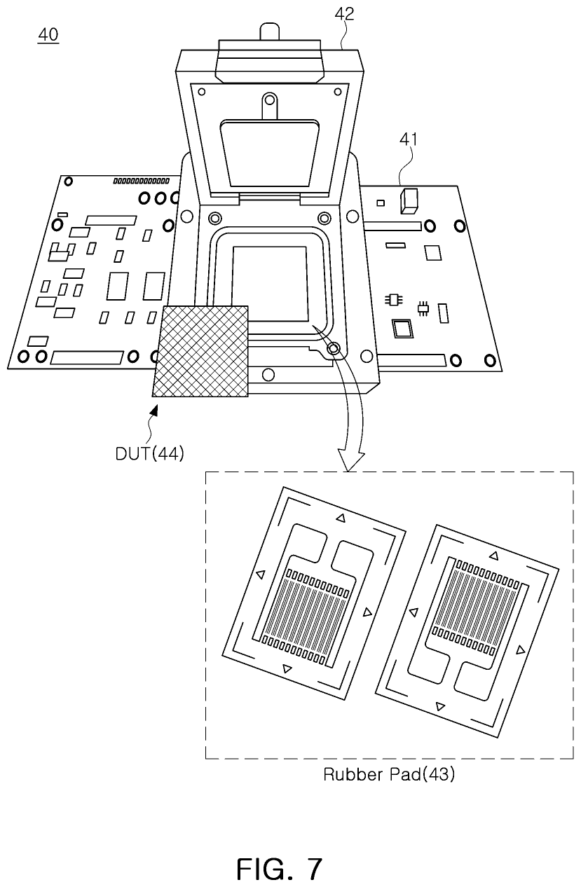

FIG. 7 is a diagram illustrating a semiconductor test device 40 according to an example embodiment. Referring to FIG. 7, the semiconductor test device 40 may include a test chip 41, a test socket 42, a rubber pad 43, and a device under test (DUT) 44.

In an embodiment, the test socket 42 may be compressed into a seating portion disposed on the test chip 41 to electrically connect the test chip 41 and the device under test 44 through the rubber pad 43. In an embodiment, the rubber pad 43 may include a plurality of micro balls.

When a semiconductor product is mounted on the rubber pad 43 and the test socket 42 is closed and force (e.g., pressure) is applied thereto, conductive microballs of a gold component may be relatively strongly pressed to be electrically connected to a terminal of the test under device 44 during a testing operation.

In an embodiment, the rubber pad 43 is formed of a soft rubber material, which may reduce damage to the semiconductor terminal. In an example embodiment, the rubber pad 43 may be implemented with the ECTI.

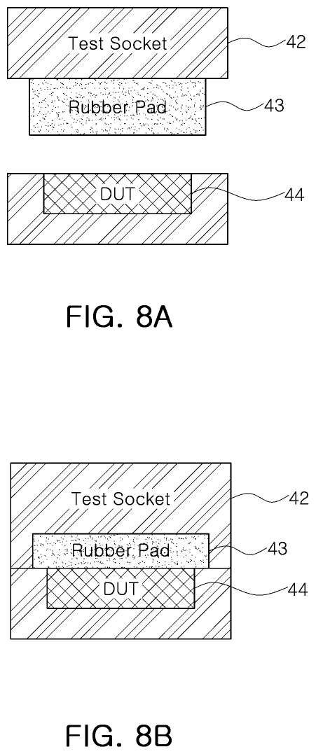

FIGS. 8A and 8B are diagrams illustrating a state before a test socket 42 illustrated in FIG. 7 is closed and a state in which the test socket 42 is closed. As illustrated in FIG. 8A, the test chip 41 and the device under test 44 are not electrically connected before the test socket 42 is closed. However, in an embodiment as illustrated in FIG. 8B, after closing the test socket 42, the test chip 41 and the device under test 44 may be electrically connected through the rubber pad 43. For example, the rubber pad 43 attached to the test socket 42 may be seated on the device under test (DUT) to be electrically connected to the test chip 41.

In an embodiment, the ECTI according to an example embodiment may be applied to a test board.

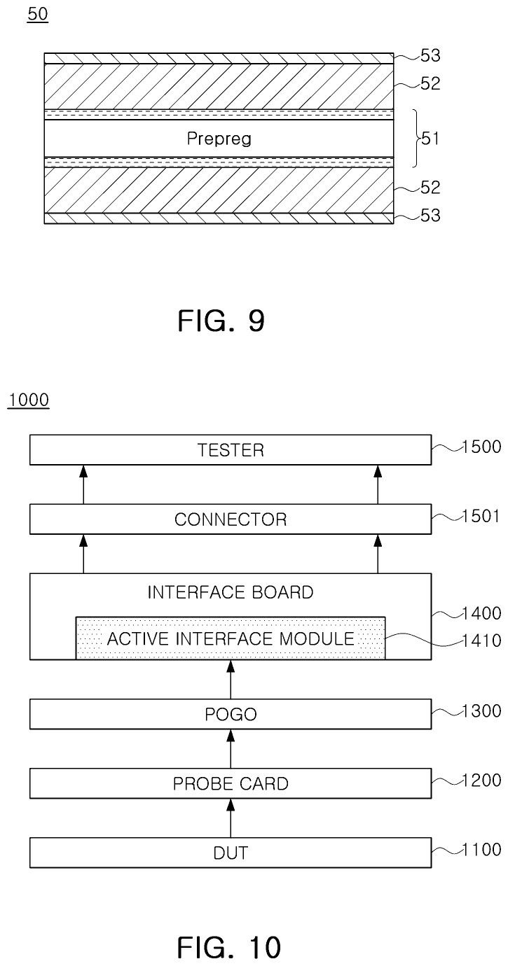

FIG. 9 is a diagram illustrating a test board 50 according to an example embodiment. Referring to FIG. 9, the test board 50 may include a plurality of laminates 51, a substrate 52, and a copper foil layer 53. In an embodiment, the test board 50 may include a test integrated circuit. In an example embodiment, the test board 50 may be a printed circuit board (PCB).

The laminates 51 serve as a basic framework or foundation for the test board 50 and may be implemented to provide a surface on which electronic components are attached and an internal electrical connection. In an example embodiment, pre-impregnated (e.g., prepreg) serves as an adhesive between the plurality of laminates 51. While an embodiment of FIG. 9 shows the plurality of laminates including three laminate layers, embodiments of the present inventive concept are not necessarily limited thereto.

The substrate 52 is disposed above/below the laminates 51 and may include a test chip. The copper foil layer 53 may be disposed above/below the substrate 52 and electrically connected to the substrate 52. In an example embodiment, the copper foil layer 53 may include the ECTI.

According to an embodiment of the present inventive concept, the ECTI is applied to manufacture the PCB to prevent heat conduction.

FIG. 10 is a diagram illustrating a test system 1000 (e.g., a semiconductor test device) according to an example embodiment. Referring to FIG. 10, the test system 1000 may include a probe card 1200, a pogo block (POGO) 1300, an interface board 1400, a test device (e.g., a tester) (ATM) 1500, and a connector 1501 between the tester 1500 and the interface board 1400.

The probe card 1200 may be provided to perform a test process to test electrical characteristics of a device under test (DUT). For example, in an embodiment the probe card 1200 may be provided to perform an electric die sorting (EDS) process of applying an electrical signal to image sensors formed on a wafer and determining whether the image sensors are defective by signals output from the image sensors in response to the applied electrical signal. In addition, the probe card 1200 may be applied to any test process to test whether a plurality of image sensors are defective.

For example, the probe card 1200 may apply an electrical signal provided from the test device 1500, for example, at least one of power and a signal, to a wafer including a plurality of image sensors, and provide a signal output in response to the applied electrical signal to the test device 1500. The probe card 1200 may contact pads of the device under test. For example, in an embodiment, while the test process is in progress, probe pins may come into physical contact with a pad on the wafer to transmit an electrical signal to the wafer or receive a signal output from the wafer. In an embodiment, at least some of the probe pins may be input probe pins for transmitting an electrical signal provided from the test device 1500 to the wafer. In addition, at least some of the probe pins may be output probe pins for receiving an electrical signal output from the wafer. These probe pins may be referred to as probe needles or probes. In an example embodiment, the probe card 1200 may be a cantilever probe card, a vertical probe card, a membrane probe card, or a micro electro mechanical system (MEMS) probe card. However, embodiments of the present inventive concept are not necessarily limited thereto.

The pogo block (POGO) 1300 may include a plurality of pins for connecting the probe card 1200 and the interface board 1400 to each other. In an embodiment, each of the plurality of pins may include a POGO pin. The pogo block 1300 may receive output signals from the probe card 1200.

The interface board 1400 may be implemented to map the probe card 1200 and the test device 1500. The interface board 1400 may receive output signals from the probe card 1200. In addition, the interface board 1400 may include an active interface module 1410. The active interface module 1410 may be implemented to correspond to a communication standard of the DUT 1100. In an example embodiment, the active interface module 1410 may be implemented in a modular type to be inserted into the interface board 1400 through a module connector. For example, the active interface module 1410 may be implemented in any one of mobile industry processor interfaces (MIPI) C—PHY, MIPI D-PHY, MIPI M-PHY, and MIPI A-PHY. MIPI is a serial interface connecting hardware and software between a processor and peripheral devices. However, embodiments of the present inventive concept are not necessarily limited to the aforementioned MIPI standards. The active interface module 1410 of the present inventive concept may perform communication according to any type of communication interface corresponding to a serial interface standard output from a CMOS image sensor.

The test device 1500 may be implemented to transmit input and control signals to at least one image sensor through the probe card 1200. The test device 1500 may be implemented to simultaneously test the DUT 1100. In an embodiment, the DUT 1100 may include a wafer having a plurality of image sensors. In an example embodiment, the test device 1500 may be connected to the interface board 1400 through a signal connector 1501 (e.g., a connector).

To receive a high-speed signal, in the test system 1000 according to an example embodiment, the active interface module 1410, which receives the high-speed signal, may be located to be closest to the wafer 1100. In general, high-speed signals require relatively small lengths and contact structures to reduce loss. As a signal speed increases, signal loss may occur between the pogo block 1300 and the interface board 1400. In an example embodiment, the active interface module 1410 may additionally include a signal compensation circuit compensating for reducing loss between the wafer 1100 and the probe card 1200 and between the pogo block 1300 and the interface board 1400. In an example embodiment, the active interface module 1410 may include a differential signal generating circuit advantageous for relatively long distances. In an example embodiment, the active interface module 1410 may include a standard response circuit that may respond even if an interface output from the wafer 1100 is changed. The active interface module 1410 may modularize the aforementioned signal compensation circuit, long-distance signal generating circuit, and standard response circuit.

In an example embodiment, any one of the probe card 1200, pogo block 1300, interface board 1400, and signal connector 1501 may include pins formed of the ECTI or may include pins having a buckled column-shaped bending structure.

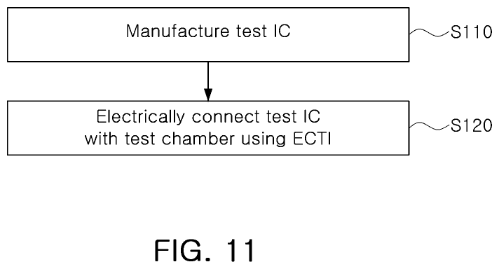

FIG. 11 is a flowchart illustrating a method of manufacturing a semiconductor test device according to an example embodiment. Referring to FIGS. 1 to 11, the semiconductor test device may be manufactured as follows.

A test board may be manufactured in block S110. The test board may be electrically connected to the test chamber using the ECTI in block S120. In an example embodiment, a copper foil layer of the test board may be formed using the ECTI. In an example embodiment, pins having a bending structure may be formed using the ECTI. In an example embodiment, each of the pins may be implemented in a column (e.g., a buckled column) structure. In an example embodiment, compressed to the test board, a test socket electrically connected to a device under test through a rubber pad may be manufactured.

The device described above may be implemented with hardware components, software components, and/or a combination of hardware components and software components. For example, in some embodiments the devices and components described in the example embodiments may be implemented using one or more general-purpose or special-purpose computers, such as a processor, a controller, an arithmetic logic unit (ALU), a digital signal processor, a microcomputer, a field programmable gate array (FPGA), a programmable logic unit (PLU), a microprocessor, or any other device capable of executing and responding to instructions. A processing device may execute an operating system (OS) and one or more software applications run on the operating system. In addition, the processing device may access, store, manipulate, process, and generate data in response to the execution of software. For ease of understanding, a single processing device may be described as being used. However, embodiments of the present inventive concept are not necessarily limited thereto and a processing device including multiple processing elements or multiple types of processing elements may be used. For example, the processing device may include a plurality of processors or one processor and one controller. In addition, other processing configurations, such as parallel processors, are also possible.

In an embodiment, software may include a computer program, code, instructions, or a combination of one or more thereof, and may configure a processing device to operate as desired or to issue a command to the processing device independently or collectively. In an embodiment, software and/or data may be embodied in any type of machine, component, physical device, virtual equipment, computer storage medium or device to be interpreted by, or to provide instructions or data to, the processing device. In an embodiment, software may be distributed in networked computer systems and stored or executed in a distributed manner. In an embodiment, the software and data may be stored in one or more computer-readable recording mediums.

According to an embodiment of the present inventive concept, a semiconductor test device has an ECTI applied to a test signal connection structure that transmits electrical signals from a device under test in a chamber to a test module. In an example embodiment, the semiconductor test device applies the ECTI to an electrical signal connection portion of the test signal connection structure and a non-electrically conductive material to portions other than the electrical signal connection structure. In an example embodiment, in the semiconductor test device, the test signal connection structure includes cables, sockets, probe cards, printed circuit boards (PCBs), low temperature co-fired ceramic (LTCC), and the like. In an example embodiment, the test signal connection structure included in the sockets and probe cards have a bending structure.

According to an embodiment of the present inventive concept, a problem in which a test defect occurring due to unnecessary heat transfer between a chamber and a test module when a distance between the DUT and the test module is reduced using the existing electrical signal connection device (e.g., Cu, Ag, etc.) in implementing a chamber-type one-test facility platform may be prevented.

In an embodiment in which the ECTI is applied to the semiconductor test device, the number of products that may be tested simultaneously per unit area may be increased, and budget may be reduced due to a reduction in high temperature↔low temperature variable time due to insulation and an increase in facility energy efficiency, while maintaining high-speed signal test performance in extreme temperature environments.

In the semiconductor test device and method of manufacturing the same according to an example embodiment, heat exchange between the test chamber and the device under test may be reduced by using the ECTI, thereby reducing a test process time without distorting signals transmitted and received between the test module and the device under test in a wide temperature range.

While non-limiting, example embodiments have been illustrated and described above, it will be apparent to those skilled in the art that modifications and variations could be made to the described example embodiments without departing from the scope of the present inventive concept.

1. A semiconductor test device comprising:
a test chamber having at least one device under test disposed therein;
a test module testing the at least one device under test; and
a signal connection device electrically connecting the at least one device under test and the test module to each other,
wherein the signal connection device includes an electrically conductive thermal insulator (ECTI), and
wherein the ECTI has electrical conductivity greater than or equal to about 1700 S/cm and thermal conductivity less than or equal to about 2.2 W/mK.

2. The semiconductor test device of claim 1, wherein the test chamber, the test module, and the signal connection device are a chamber-type one-test device.

3. The semiconductor test device of claim 1, wherein the ECTI includes at least one of Al₂O₃-graphene nanocomposite material, Bi—Si nanocomposite material, carbon-ceramic electrospun nonwoven material, carbon nanotube sponge, multi-nanolayer graphene/ceramic metamaterial, and poly(3,4-ethylenedioxythiophene) polystyrene sulfonate.

4. The semiconductor test device of claim 1, further comprising an air supply device supplying air to control a temperature of the test chamber.

5. The semiconductor test device of claim 4, wherein the test chamber further includes a temperature sensor detecting the temperature.

6. The semiconductor test device of claim 1, wherein the test module includes a cooling pipe through which a refrigerant flows to control a test temperature of the test module.

7. The semiconductor test device of claim 1, wherein the signal connection device includes at least one of a cable, a socket, a probe card, a printed circuit board, and a low temperature co-fired ceramic.

8. The semiconductor test device of claim 7, wherein at least one of the socket and the probe card includes a pin having a bending structure having the ECTI.

9. The semiconductor test device of claim 8, wherein the pin has a buckled column structure.

10. The semiconductor test device of claim 1, wherein the semiconductor test device performs burn-in testing, high-speed signal testing and low-speed signal testing.

11. A semiconductor test device comprising:
a probe card contacting pads of a device under test;
a pogo block receiving output signals from the probe card;
an interface board receiving output signals from the pogo block, converting the received signals, and outputting the converted signals through a signal connector; and
a test device connected to the interface board through the signal connector, the test device testing the device under test through signals received through the signal connector,
wherein at least one of the probe card, pogo block, interface board, and signal connector includes pins formed of an electrically conductive thermal insulator (ECTI), and
wherein the ECTI has electrical conductivity greater than or equal to about 1700 S/cm and thermal conductivity less than or equal to about 2.2 W/mK.

12. The semiconductor test device of claim 11, wherein each of the pins has a bending structure.

13. The semiconductor test device of claim 11, wherein each of the pins has a buckled column structure.

14. The semiconductor test device of claim 11, wherein the test device transmits signals between a transmitter and a receiver by the ECTI.

15. The semiconductor test device of claim 11, wherein the test device includes at least one printed circuit board, and the printed circuit board includes a copper foil layer having the ECTI.

16. A semiconductor test device comprising:
a rubber pad having a plurality of micro balls;
a test board receiving a device under test and testing the device under test; and
a test socket pressed against the test board to electrically connect the device under test and the test board through the rubber pad,
wherein the rubber pad is formed of an electrically conductive thermal insulator (ECTI), and
wherein the ECTI has electrical conductivity greater than or equal to about 1700 S/cm and thermal conductivity less than or equal to about 2.2 W/mK.

17. The semiconductor test device of claim 16, wherein the rubber pad is compressed by the test socket when the test socket presses against the test board.

18. The semiconductor test device of claim 16, wherein:
before closing the test socket, the test board and the device under test are not electrically connected to each other; and
after closing the test socket, the test board and the device under test are electrically connected to each other.

19. The semiconductor test device of claim 16, wherein the test board includes a copper foil layer using the ECTI.

20. The semiconductor test device of claim 16, wherein the test board is disposed below or above the copper foil layer, the test board further including a dielectric preventing heat conduction.

21-25. (canceled)
